(19) United States
(12) Patent Application Publication
(10) Pub. No.: US 2024/0287668 A1
(43) Pub. Date: Aug. 29, 2024

(54) DLC FILM DEPOSITION APPARATUS, SEMICONDUCTOR MANUFACTURING SYSTEM INCLUDING THE DLC FILM DEPOSITION APPARATUS, AND SEMICONDUCOR MANUFACTURING METHOD USING THE DLC FILM DEPOSITION APPARATUS

(71) Applicant: Samsung Electronics Co., Ltd., Suwon-si (KR)

(72) Inventors: Se Jun PARK, Suwon-si (KR); Do Hyung KIM, Suwon-si (KR); Se-Ung MIN, Suwon-si (KR); Ju Hwan PARK, Suwon-si (KR); Myung Seok SONG, Suwon-si (KR); Moon Seok JANG, Suwon-si (KR); Young Soo JUNG, Suwon-si (KR)

(21) Appl. No.: 18/443,517

(22) Filed: Feb. 16, 2024

(30) Foreign Application Priority Data
Feb. 16, 2023 (KR) 10-2023-0020749
Apr. 21, 2023 (KR) 10-2023-0052646

(51) Int. Cl. C23C 14/06; C23C 14/34; C23C 14/50; C23C 16/27; C23C 16/44; H01L 21/02; H01L 21/67; H01L 21/683

(52) U.S. Cl. CPC C23C 14/0611; C23C 14/3407; C23C 14/50; C23C 16/27; C23C 16/4408; H01L 21/02115; H01L 21/02266; H01L 21/67017; H01L 21/6833

(57) ABSTRACT

A DLC film deposition apparatus comprises a chamber in which processes are performed, a substrate in the chamber, the substrate having a first surface facing the top of the chamber, and a second surface opposite to the first surface, a holder in the chamber, the holder configured to support the substrate while being in contact with part of the second surface of the substrate, and a DLC film generator below the substrate, in the chamber, the DLC film generator configured to deposit a DLC film on the second surface of the substrate, wherein the DLC film is formed on the part of the second surface of the substrate that is not in contact with the holder.

### CROSS-REFERENCE TO RELATED APPLICATION

This application claims priority from Korean Patent Application Nos. 10-2023-0020749, filed on Feb. 16, 2023 and No. 10-2023-0052646, filed on Apr. 21, 2023 in the Korean Intellectual Property Office, and all the benefits accruing therefrom under 35 U.S.C. 119, the contents of which in their entireties are herein incorporated by reference.

### BACKGROUND

### 1. Technical Field

The present disclosure relates to a diamond-like carbon (DLC) film deposition apparatus, a semiconductor manufacturing system including the DLC film deposition apparatus, and a semiconductor manufacturing method using the DLC film deposition apparatus

### 2. Description of the Related Art

As the number of levels of a Vertical-Not-AND (VNAND) product increases, the likelihood of deformation of a substrate increases due to the number of films stacked on the substrate. To prevent the deformation of the substrate during etching and thin-film deposition processes, the substrate may be clamped onto an electrostatic chuck. However, the back side of the substrate may be damaged by a chucking force from the electrostatic chuck, causing defects such as a decrease in yield. Accordingly, research is underway into ways to prevent the back side of the substrate from being damaged during the processing of the substrate with the electrostatic chuck.

### SUMMARY

Aspects of the present disclosure provide a diamond-like carbon (DLC) film deposition apparatus with an improved substrate processing yield.

Aspects of the present disclosure also provide a semiconductor manufacturing system with an improved substrate processing yield.

Aspects of the present disclosure also provide a semiconductor manufacturing method with an improved substrate processing yield.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

In accordance with an aspect of the disclosure, a diamond-like carbon (DLC) film deposition apparatus includes a chamber; a holder in the chamber, the holder configured to support a mounted substrate while being in contact with part of a second surface of the mounted substrate, wherein the mounted substrate is a substrate placed on the holder and having a first surface facing the top of the chamber and the second surface opposite to the first surface; and a DLC film generator below the holder, in the chamber, the DLC film generator configured to deposit a DLC film on the second surface of the mounted substrate.

In accordance with an aspect of the disclosure, a semiconductor manufacturing system includes a first chamber; a diamond-like carbon (DLC) film deposition module configured to deposit a DLC film on a second surface of a substrate, the substrate, when disposed in the first chamber, having a first surface facing the top of the first chamber and the second surface opposite to the first surface; and a substrate processing module including a second chamber different from the first chamber and an electrostatic chuck, the electrostatic chuck configured to support the second surface of the substrate, the substrate processing module configured to process the first surface of the substrate with the DLC film deposited on the second surface; and a holder in the chamber and configured to support part of the second surface of the substrate while the DLC film deposition module is depositing the DLC film on the second surface of the substrate, wherein: while the DLC film deposition module is depositing the DLC film on the second surface of the substrate, a part of the second surface of the substrate is supported by the holder in the first chamber, and the electrostatic chuck is configured to fix the substrate such that the DLC film and an upper surface of the electrostatic chuck face each other while the substrate processing module is processing the first surface of the substrate.

In accordance with an aspect of the disclosure, a method of manufacturing a semiconductor device includes depositing a diamond-like carbon (DLC) film on a second surface of a substrate, the substrate having a first surface facing the top of a first chamber, and the second surface opposite to the first surface; in a second chamber different from the first chamber, fixing the substrate on an electrostatic chuck such that the DLC film and an upper surface of the electrostatic chuck face each other; and processing the first surface of the substrate with the substrate clamped on the electrostatic chuck, in the second chamber.

In accordance with an aspect of the disclosure, a method of depositing a diamond-like carbon (DLC) film includes providing a chamber in which processes are performed; placing a substrate on a holder in the chamber, the substrate having a first surface facing the top of the chamber and a second surface opposite to the first surface; depositing the DLC film on the second surface of the substrate using a DLC film generator below the holder.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a schematic view of a DLC film deposition module according to some embodiments of the present disclosure.

FIG. 2 is a schematic view of a DLC film deposition module according to some embodiments of the present disclosure.

FIG. 3 is a schematic view of a DLC film deposition module according to some embodiments of the present disclosure.

FIGS. 4 through 6 are schematic views illustrating a substrate having a DLC film formed thereon by the DLC film deposition module of any one of FIGS. 1 through 3.

FIG. 7 is a schematic view of a removal module according to some embodiments of the present disclosure.

FIG. 8 is a schematic view of a removal module according to some embodiments of the present disclosure.

FIG. 9 is a schematic view of a substrate processing module according to some embodiments of the present disclosure.

FIG. 10 is a schematic view of an example of the substrate processing module of FIG. 9.

FIG. 11 is a schematic view of a semiconductor manufacturing system according to some embodiments of the present disclosure.

FIG. 12 is a schematic view of a semiconductor manufacturing system according to some embodiments of the present disclosure.

FIG. 13 is a flowchart illustrating a semiconductor manufacturing method according to some embodiments of the present disclosure.

FIGS. 14 and 15 are flowcharts illustrating how to deposit a DLC film, as performed in the semiconductor manufacturing method of FIG. 13.

FIG. 16 is a flowchart illustrating how to remove a DLC film, as performed in the semiconductor manufacturing method of FIG. 13.

### DETAILED DESCRIPTION

A diamond-like carbon (DLC) film deposition apparatus, a semiconductor manufacturing system including the DLC film deposition apparatus, and a semiconductor manufacturing method using the DLC film deposition apparatus according to some embodiments of the present disclosure will hereinafter be described with reference to the accompanying drawings.

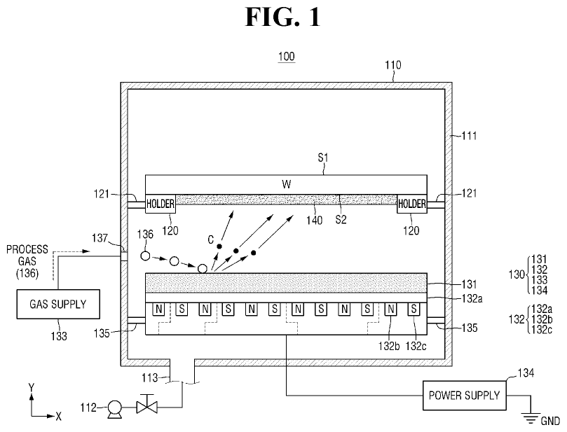

FIG. 1 is a schematic view of a DLC film deposition module according to some embodiments of the present disclosure.

Referring to FIG. 1, a DLC film deposition module 100 may include a chamber 110, a substrate W, a holder 120, and a DLC film generator 130.

The chamber 110 may process the substrate W using plasma generated therein and may provide space in which to fabricate a semiconductor device. For example, the chamber 110 may be a deposition chamber for depositing thin films on the back side of the substrate W. The chamber 110 may have a sealed space with a particular size therein to process the substrate W. The sealed space in the chamber 110 may be in a vacuum- or near-vacuum state. The chamber 110 may be formed in various shapes depending on the size of the substrate W. For example, the chamber 110 may have a cylindrical shape to correspond to the shape of the substrate W, which is disk-shaped, but the invention is not limited thereto. The chamber 110 may include a conductive material such as aluminum (Al). In order to block noise from the outside, the chamber 110 may be maintained in an electrical ground state while processes are being performed therein.

A liner 111 may be disposed on the inside of the chamber 110 (e.g., on the inside surface of the chamber 110. The liner 111 may protect the chamber 110 and may cover the metal structure in the chamber 110 to prevent metal contamination that may be caused by arcing in the chamber 110. The liner 111 may be formed of a metal material such as Al or a ceramic material. The liner 111 may also be formed of a material film resistant to plasma, in an area in the chamber 110 where plasma is generated. Here, the material film may be, for example, an yttrium oxide (Y₂O₃) film, but the invention is not limited thereto.

An outlet 113, which is connected to a vacuum pump 112 such as a dry pump, may be formed at the bottom of the chamber 110. Byproducts generated in the chamber 110 may be discharged through the outlet 113. The vacuum pump 112 may control the pressure in the chamber 110.

The substrate W, which is disposed inside the chamber 110, may refer to the substrate W alone or a stack structure including the substrate W and a layer or film formed on the substrate W. Also, the surface of the substrate W may refer to the exposed surface of the substrate W or the exposed surface of the layer or film formed on the substrate W. For example, the substrate W may be a wafer or may include a wafer and at least one material film on the wafer. The material film on the wafer may be an insulating film and/or a conductive film formed by various methods such as deposition, coating, and plating. For example, the insulating film may be an oxide film, a nitride film, or an oxynitride film, and the conductive film may include a metal film or a polysilicon film. The material film may be formed on the wafer to have a predetermined pattern.

The substrate W may have a first surface S1, which faces the top of the chamber 110, and a second surface S2, which is opposite to the first surface S1. The second surface S2 of the substrate W may be disposed to face the bottom of the chamber 110. The top and the bottom of the chamber 110 may be determined with respect to a first direction Y as shown, e.g., in FIG. 1.

The first surface S1 of the substrate W may correspond to the front side of the substrate W, and the second surface S2 of the substrate W may correspond to the back side of the substrate W. A pattern may be formed on the first surface S1 of the substrate W before a process to be performed by the DLC film deposition module 100. Alternatively or additionally, a pattern may be formed on the first surface S1 of the substrate W after the formation of a DLC film 140 on the second surface S2 by the DLC film deposition module 100.

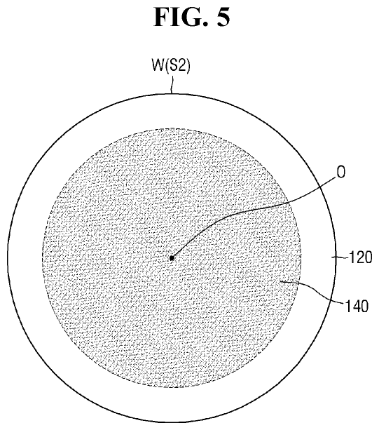

The holder 120 may support the substrate W in the chamber 110. The holder 120 may be supported by a support member 121, which is fixed to the inner sidewall of the chamber 110. The holder 120 may be disposed below the substrate W and may support the substrate W while being in contact with the second surface S2 of the substrate W. The holder 120 may support the substrate W while being in contact with only part of the second surface S2 of the substrate W. For example, the holder 120 may support the substrate W while being in contact with only the edge of the second surface S2 of the substrate W. Accordingly, part of the second surface S2 of the substrate W not being supported by the holder 120 (e.g., a central part of the second surface S2 of the substrate W) may be exposed. The structure of the holder 120 will be described later with reference to FIG. 5.

The DLC film generator 130 may be disposed below the substrate W and the holder 120, in the chamber 110. The DLC film generator 130 may deposit the DLC film 140 on part of the second surface S2 of the substrate W not being in contact with the holder 120. The DLC film 140 is a carbon (C) film having an amorphous structure with diamond-like properties and may have high hardness and a low friction coefficient.

In some embodiments, the DLC Film 140 may be deposited on the second surface S2 of the substrate W by a physical vapor deposition (PVD) process via sputtering. The DLC film generator 130 may include a sputtering target 131, a sputtering target supporter 132, a gas supply 133, and a power supply 134.

The sputtering target 131 may be disposed to face the second surface S2 of the substrate W, in the chamber 110. The sputtering target 131 may include graphite, which consists of C atoms. The sputtering target supporter 132 may have an upper surface where the sputtering target 131 is loaded. The sputtering target supporter 132 may be supported by a support 135, which is fixed to the inner sidewall of the chamber 110. The sputtering target supporter 132 may support the sputtering target 131 and may function as a passage for supplying power to generate plasma in the space between the substrate W and the sputtering target. For example, the sputtering target supporter 132 may be connected to the power supply 134 to provide power from the power supply 134 to a process gas 136 through the sputtering target 131. The sputtering target supporter 132 may include a copper (Cu) plate 132a, an N-pole magnet 132b, and an S-pole magnet 132c. A cooling water line may be provided to cool the sputtering target 131 during sputtering.

The gas supply 133 may inject the process gas 136 into the space between the substrate W and the sputtering target 131, in the chamber 110. The gas supply 133 may supply the process gas 136 into the chamber 110 through a supply device 137 such as nozzles or potholes installed on the sidewall of the chamber 110. The process gas 136 may be a sputtering gas and may include argon (Ar), nitrogen (N₂), or oxygen (O₂), but the invention is not limited thereto.

The power supply 134 may output power appropriate for the generation of power. The power output by the power supply 134 may be radio frequency (RF) power or direct current (DC) power. The sputtering target 131 may be a graphite target, and the power supply 134 may be an RF power supply. An RF signal output from the power supply 134 may be applied to the sputtering target supporter 132 through a matching circuit (or a matcher). The sputtering target 131 and the substrate W may be charged as an anode and a cathode, respectively, by an RF voltage supplied by the power supply 134. When electrons emitted from the sputtering target 131 collide with the process gas 136, moving toward the substrate W, which is a cathode, the process gas 136 may be ionized and may thus become plasma.

The ionized process gas may be rapidly accelerated toward the sputtering target 131, which is an anode due to having the properties of positive ions. When the accelerated ionized process gas collides with the sputtering target 131, electrons and C atoms may pop out of the sputtering target 131. Then, the electrons may combine with the ionized process gas, and the C atoms may be deposited on the second surface S2 of the substrate W, thereby forming the DLC film 140.

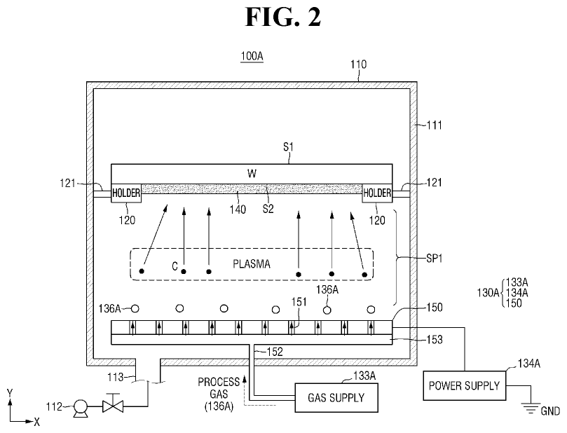

FIG. 2 is a schematic view of a DLC film deposition module according to some embodiments of the present disclosure. The embodiment of FIG. 2 will hereinafter be described, focusing mainly on the differences with the embodiment of FIG. 1.

Referring to FIG. 2, a DLC film generator 130A of a DLC film deposition module 100A may deposit a DLC film 140 on a second surface S2 of a substrate W via chemical vapor deposition (CVD). The DLC film generator 130A may include a gas supply 133A, a showerhead 150, and a power supply 134A.

The gas supply 133A may be disposed below a chamber 110, on the outside of the chamber 110. The gas supply 133A may inject a process gas 136A into a first space SP1 between the substrate W and the showerhead 150, in the chamber 110, through the showerhead 150. In some embodiments, the process gas 136A may include a hydrocarbon gas such as CH₄, C₂H₂, C₃H₆, C₆H₆, or C₆H₁₂.

The showerhead 150 may be disposed to face the second surface S2 of the substrate W. The showerhead 150 may be disposed below the substrate W and a holder 120, in the chamber 110, and a plurality of gas diffusion holes 151 may be formed in the showerhead 150. The gas supply 133A may be connected to a gas supply pipe 152, which is for supplying the process gas 136A to the substrate W in the chamber 110. The gas supply pipe 152 may be connected to the showerhead 150, which has the gas diffusion holes 151 formed therein, through a buffer 153 and may spray the process gas 136A onto the second surface S2 of the substrate W supported by the holder 120.

The power supply 134A may supply power to the process gas 136A to generate a hydrocarbon gas plasma in the first space SP1 between the substrate W and the showerhead 150. Power output by the power supply 134A may be RF power or DC power. The holder 120 may be in an electrical ground state. The process gas 136A may be a hydrocarbon gas, and the power supply 134A may be an RF power supply. An RF signal output from the power supply 134A may be applied to the showerhead 150 through a matching circuit (or a matcher).

The process gas 136A provided from the gas supply 133A to the first space SP1 through the gas supply pipe 152 and the showerhead 150 may receive RF power from the power supply 134A and may thus be turned into plasma. C atoms included in the hydrocarbon gas plasma may be deposited on the second surface S2 of the substrate W, thereby forming the DLC film 140. The DLC Film 140 may be deposited on the second surface S2, which is the back side of the substrate W, using hydrocarbon gas plasma generated in the chamber 110 via a capacitively-coupled plasma (CCP) method, but the invention is not limited thereto. Alternatively, the DLC film 140 may be deposited on the second surface S2 by generating plasma in the chamber 110 via an inductively-coupled plasma (ICP) method.

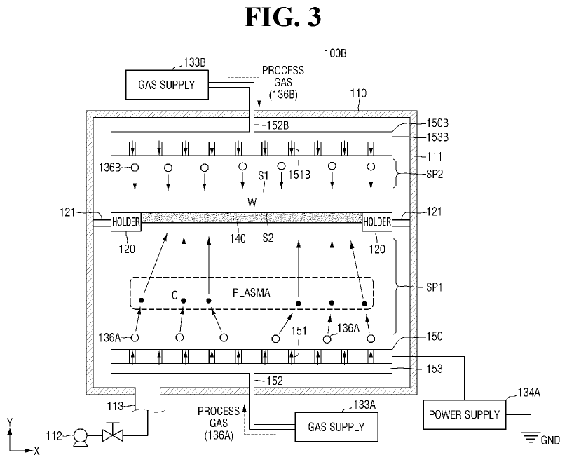

FIG. 3 is a schematic view of a DLC film deposition module according to some embodiments of the present disclosure. The embodiment of FIG. 3 will hereinafter be described, focusing mainly on the differences with the embodiment of FIG. 2.

Referring to FIG. 3, a DLC film deposition module 100B, unlike the DLC film deposition module 100A of FIG. 2, may further include a gas supply 133B and a showerhead 150B. The gas supply 133B may be disposed above a chamber 110, on the outside of the chamber 110. The gas supply 133B may inject a process gas 136B into a second space SP2 between a substrate W and the showerhead 150B through the showerhead 150B.

The showerhead 150B may be disposed above the substrate W, in the chamber 110, to face a first surface S1 of the substrate W. The gas supply 133B and the showerhead 150B may be connected via a gas supply pipe 152B. The gas supply pipe 152B may be connected to the showerhead 150B, in which a plurality of gas diffusion holes 151B are formed, through a buffer 153B and may spray the process gas 136B onto the first surface S1 of the substrate W.

In some embodiments, the process gas 136B may be a purge gas such as N₂, O₂, or Ar. That is, while a CVD process is being performed to deposit a DLC film 140 on a second surface S2 of the substrate W, the process gas 136B may be sprayed onto the first surface S1 of the substrate W through the gas supply 133B and the showerhead 150B to prevent C atoms in a plasma state, which are generated in a first space SP1, from being accidentally deposited on the first surface S1 of the substrate W.

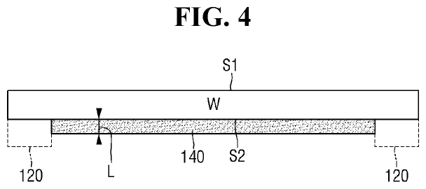

FIGS. 4 through 6 are schematic views illustrating a substrate having a DLC film formed thereon by the DLC film deposition module of any one of FIGS. 1 through 3.

Referring to FIGS. 4 and 5, a DLC film 140 may be deposited on a second surface S2 of a substrate W by the DLC film deposition module 100, 100A, or 100B. The DLC film 140 may be deposited in a central area of the second surface S2 of the substrate W that is not in contact with the holder 120 during a deposition process performed by the DLC film deposition module 100, 100A, or 100B. As illustrated in FIG. 5, in a case where the holder 120 is in the shape of a ring supporting the edge of the substrate W, which is disk-shaped, the DLC film 140 may be deposited on the second surface S2 of the substrate W as a concentric circle with the circle shape of the substrate W. However, the shapes of the holder 120 and the DLC film 140 are not particularly limited. In other words, the holder 120 may be implemented in various shapes other than a ring shape to support the edge of the second surface S2 of the substrate W.

The DLC film 140, which is deposited on the second surface S2 of the substrate W, may have a hardness of 10 GPa to 50 Gpa. The DLC film 140 may have a thickness L of 10 nm to 500 nm. If the DLC film 140 has a hardness less than 10 Gpa or has a thickness L less than 10 nm, the second surface S2 of the substrate W, which is the back side of the substrate W, may not be properly supported during the processing of a first surface S1 of the substrate W, which is the front side of the substrate W, and as a result, scratches or defects may be formed on the back side of the substrate W, resulting in a decrease in semiconductor manufacturing yield. On the contrary, if the DLC film 140 has a hardness greater than 50 Gpa or has a thickness L greater than 500 nm, the chucking force for fixing or clamping the substrate W with an electrostatic chuck may not be sufficient so that the substrate W may not be properly supported.

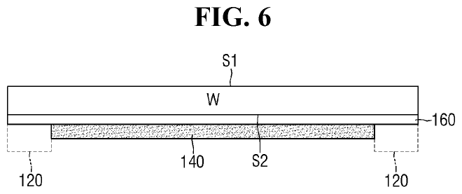

Referring to FIG. 6, in some embodiments, the DLC film 140 may be deposited with a silicon (Si) film 160 already deposited on the second surface S2 of the substrate W. The Si film 160 may include silicon oxide (SiO₂) or silicon nitride (SiN). The Si film 160, which is deposited on the second surface S2 of the substrate W, may be for improving the warpage of the substrate W that may be caused by stress applied to the substrate W during the deposition or etching of various thin films on the first surface S1 of the substrate W. As the DLC film 140 is additionally deposited on the second surface S2 of the substrate W, on which the Si film 160 is already deposited, the warpage of the substrate W and any scratches and defects on the back side of the substrate W during a deposition or etching process performed on the first surface S1 of the substrate W can be improved at the same time.

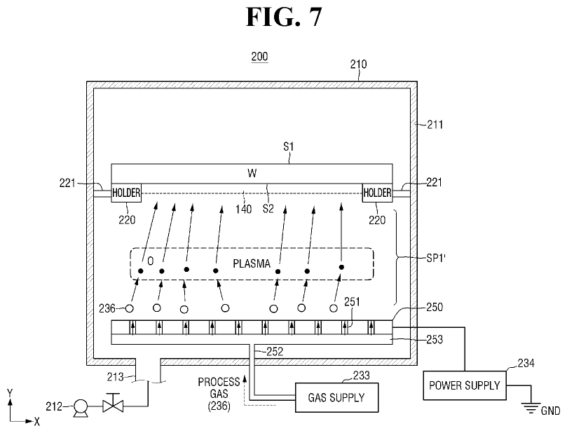

FIG. 7 is a schematic view of a removal module according to some embodiments of the present disclosure.

Referring to FIG. 7, a DLC film 140, which is deposited on a second surface S2 of a substrate W, may be peeled off and removed from the substrate W by an ashing process, which is performed by a removal module 200, after the processing of a first surface S1 of the substrate W, which is the front side of the substrate W. The embodiment of FIG. 7 will hereinafter be described.

The removal module 200 may include a chamber 210, in which a liner 211 is disposed, the substrate W, a holder 220, a gas supply 233, a showerhead 250, a power supply 234, a vacuum pump 212, and an outlet 213. A process gas 236 may be injected into the chamber 210 through the gas supply 233 and the showerhead 250. The process gas 236 may be provided to a first space SP1′ between the substrate W and the showerhead 250, in the chamber 210. The process gas 236 may be an ashing gas and may include, for example, O₂, but the invention is not limited thereto. Alternatively, in some embodiments, the process gas 236 may include ozone (O₃). For convenience, the process gas 236 will hereinafter be described as including O₂.

When the process gas 236 is provided from the gas supply 233 into the chamber 110 through the showerhead 250, in which a plurality of gas diffusion holes 251 are formed, through a gas supply pipe 252 and a buffer 253, the power supply 234 may apply power to the process gas 236, thereby generating plasma in the chamber 110. The power supply 234 may apply RF power or microwave power to the process gas 236 via a matching circuit (or a matcher). As a result, oxygen radicals, which are the byproducts of oxygen plasma, may be generated in the chamber 210. The oxygen radicals, which are highly reactive, may react with the DLC film 140 and may thereby generate carbon monoxide (CO) or carbon dioxide (CO₂), as indicated by Formulas 1 and 2:

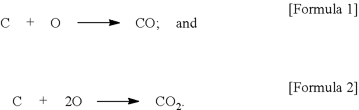

The CO or CO₂ may be released to the outside of the chamber 210 through the outlet 213, which is connected to a vacuum pump 212. The DLC film 140, which is deposited on the second surface S2 of the substrate W, may be removed from the substrate W after a photolithography, etching, or deposition process, which processes the first surface S1 of the substrate W, is complete, but the invention is not limited thereto. Alternatively, the DLC film 140, which is generated on the second surface S2 of the substrate W, may be removed from the substrate W at any time after a process that may cause scratches or defects on the back side of the substrate W is complete. For example, the DLC film 140 may be removed from the substrate W after the clamping of the substrate W with an electrostatic chuck.

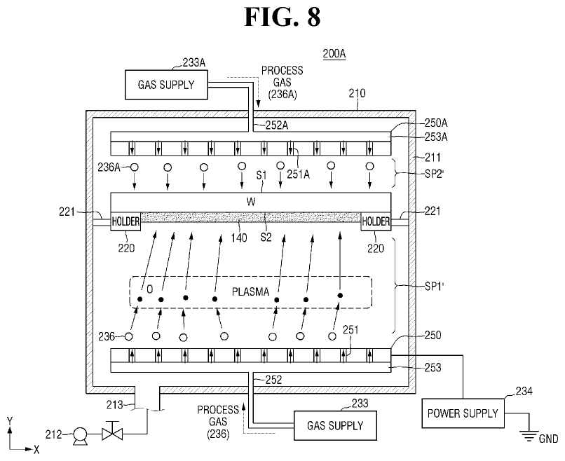

FIG. 8 is a schematic view of a removal module according to some embodiments of the present disclosure. The embodiment of FIG. 8 will hereinafter be described, focusing mainly on the differences with the embodiment of FIG. 7.

Referring to FIG. 8, a removal module 200A, unlike the removal module 200 of FIG. 7, may further include a gas supply 233A and a showerhead 250A.

The gas supply 233A may be disposed above a chamber 210 and outside of the chamber 210. The gas supply 233A may inject a process gas 236A into a second space SP2′ between a substrate W and the showerhead 250A, in the chamber 210, through the showerhead 250A.

The showerhead 250A may be disposed above the substrate W, in the chamber 210, to face a first surface S1 of the substrate W. The gas supply 233A and the showerhead 250A may be connected via a gas supply pipe 252A. The gas supply pipe 252A may be connected to the showerhead 250A, in which a plurality of gas diffusion holes 251A are formed, and may spray the process gas 236A onto the first surface S1 of the substrate W.

In some embodiments, the process gas 236A may be a purge gas such as N₂ or Ar. That is, while an ashing process, which peels off and removes the DLC film 140 from the DLC film 140, is being performed, the process gas 236A sprayed onto the first surface S1 of the substrate W through the gas supply 233A and the showerhead 250A may prevent oxygen (O) atoms in a plasma state, which are generated in a first space SP1′, from being accidentally deposited on the first surface S1 of the substrate W and oxidizing the first surface S1 of the substrate W.

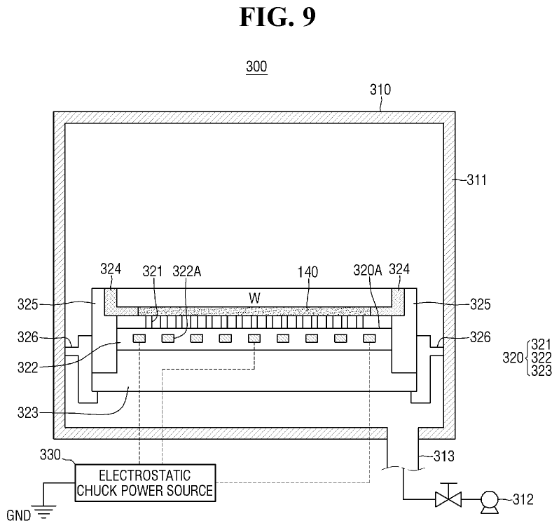

FIG. 9 is a schematic view of a substrate processing module according to some embodiments of the present disclosure.

Referring to FIG. 9, a substrate processing module 300 may include a chamber 310, a substrate W, an electrostatic chuck 320, and an electrostatic chuck power source 330. The substrate processing module 300 may process a first surface S1 of the substrate W, which is the front side of the substrate W, and may be a module performing one of a photolithography process, an etching process, and a deposition process (e.g., a CVD process).

Before the processing of the first surface S1 of the substrate W by the substrate processing module 300, a DLC film 140 may be deposited on a second surface S2 of the substrate W by one of the DLC film deposition modules 100, 100A, and 100B of FIGS. 1, 2, and 3. That is, the first surface S1 of the substrate W may be processed with the second surface S2 protected by the DLC film 140. A Si film 160 may be additionally deposited between the substrate W and the DLC film 140, as illustrated in FIG. 6.

For example, referring to FIGS. 1 and 9, after the deposition of the DLC film 140 on the second surface S2 of the substrate W, in the chamber 110 of the DLC film deposition module 100, the substrate W may be transferred into the chamber 310 of the substrate processing module 300 by a substrate transferring device (not illustrated). The chamber 110 of the DLC film deposition module 100 may differ from the chamber 310 of the substrate processing module 300 in that the electrostatic chuck 320, which is for supporting the substrate W, may be disposed in the chamber 310 instead of the holder 120 of FIG. 1.

The electrostatic chuck 320 may have an upper surface 320A, on which the substrate W is loaded. When the substrate W is loaded on the electrostatic chuck 320, the second surface S2 of the substrate W where the DLC film 140 is deposited may face the upper surface 320A of the electrostatic chuck 320. The electrostatic chuck 320 may include dimples 321 (e.g., protrusions), an electrostatic dielectric layer 322, and a base 323. A plurality of dimples 321 may be formed to protrude from the upper surface 320A of the electrostatic chuck 320. The dimples 321 may be parts of the electrostatic chuck 320 that are in direct contact with the substrate W when the substrate W is loaded on the electrostatic chuck 320. The electrostatic dielectric layer 322 may be disposed below the dimples 321. The electrostatic dielectric layer 322 may be formed of a ceramic material such as aluminum oxide (Al₂O₃), aluminum nitride (AlN), or Y₂O₃ or a dielectric material such as polyimide. The electrostatic dielectric layer 322 may have a circular shape or a disk shape.

Adsorption electrodes 322A may be embedded in the electrostatic dielectric layer 322. The adsorption electrodes 322A may be formed of a conductive material, for example, a metal such as tungsten (W), copper (Cu), nickel (Ni), molybdenum (Mo), a nickel-chromium (Ni—Cr) alloy, or a nickel-aluminum (Ni—Al) alloy or a conductive ceramic material such as tungsten carbide (WC), molybdenum carbide (MoC), or titanium nitride (TiN). The adsorption electrodes 322A may be electrically connected to the electrostatic chuck power source 330. An electrostatic force may be generated between the substrate W and the adsorption electrodes 322A by power applied from the electrostatic chuck power source 330, for example, by a DC voltage, and as a result, the substrate W may be adsorbed onto the dimples 321. The adsorption electrodes 322A may be disposed in the electrostatic dielectric layer 322 to be spaced apart from one another.

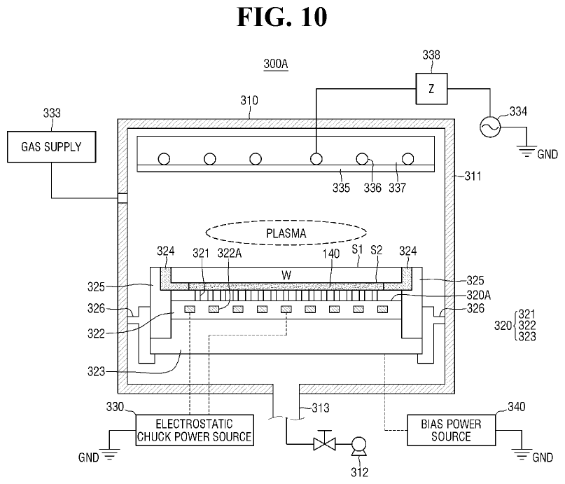

The base 323 may be disposed below the electrostatic dielectric layer 322. The electrostatic dielectric layer 322 and the base 323 may be bonded to each other by a bonding layer such as a Si layer. The base 323 will be described later with reference to FIG. 10.

In some embodiments, a focus ring 324 may be disposed along the edge of the electrostatic chuck 320. The focus ring 324 may be formed of a dielectric or insulating material to distribute an electric field on the substrate W or may include both the dielectric material and the insulating material. For example, the focus ring 324 may include at least one of Al₂O₃, AlN, Si, SiO₂, quartz, SiC, and Y₂O₃.

In some embodiments, an outer ring 325, which surrounds the focus ring 324, may be disposed. The electrostatic chuck 320 may be supported by a support member 326, which is fixed to the inner sidewall of the chamber 310 where a liner 311 is disposed. The part of the second surface S2 of the substrate W that was in contact with the holder 120 of any one of FIGS. 1, 2, and 3 when the DLC film 140 was deposited on the second surface S2 of the substrate W, i.e., an edge part of the second surface S2 of the substrate W, may be surrounded by the focus ring 324 when the substrate W is being loaded on the electrostatic chuck 320 by the substrate processing module 300 and may thus not be in direct contact with the dimples 321 of the electrostatic chuck 320. For example, the same part of the second surface S2 of the substrate W that was in contact with the holder 120 during DLC film deposition may also be in contact with the focus ring 324.

During the processing of the first surface S1 of the substrate W by the substrate processing module 300, the electrostatic chuck 320 may adsorb and clamp the substrate W with an electrostatic force and may thereby fix the substrate W horizontally. As the DLC film 140 is deposited on the second surface S2 of the substrate W, which is the back side of the substrate W, before the processing of the first surface S1 of the substrate W by the substrate processing module 300, scratches or defects that may be generated on the second surface S2 of the substrate W by the dimples 321, which are formed on the upper surface 320A of the electrostatic chuck 320, can be prevented.

FIG. 10 is a schematic view of an example of the substrate processing module of FIG. 9.

A substrate processing module 300A of FIG. 10, which is an example of the substrate processing module 300 of FIG. 9, may be a plasma treatment device etching a substrate W, which is loaded on an electrostatic chuck 320, using plasma generated in the ICP method. The electrostatic chuck 320 may also be used in an etching device using plasma generated in the CCP method. The embodiment of FIG. 10 will hereinafter be described, focusing mainly on the differences with the embodiment of FIG. 9.

Referring to FIG. 10, the substrate processing module 300A may include a chamber 310, in which a liner 311 is disposed, a substrate W, an electrostatic chuck 320, an electrostatic chuck power source 330, an RF power source 334, a bias power source 340, and a gas supply 333. A dielectric window 335, which is spaced apart from the substrate W and the electrostatic chuck 320, may be provided at the ceiling of the chamber 310. An antenna chamber 337, which accommodates a coil-shaped RF antenna 336 having a spiral or concentric circle shape, may be installed above the dielectric window 335. The RF antenna 336 may be electrically connected to the RF power source 334 through a matcher 338. The RF power source 334 may output RF power suitable for generating plasma. The matcher 338 may be provided to match the impedances of the RF power source 334 and the RF antenna 336.

The bias power source 340 may be electrically connected to the base 323. RF power may be applied from the bias power source 340 to the base 323, and thus, the base 323 may function as an electrode for generating plasma. The gas supply 333 may provide an etching gas into the chamber 310. A magnetic field may be generated around the RF antenna 336 by a current flowing through the RF antenna 336, thereby causing magnetic force lines to penetrate the chamber 310 through the dielectric window 335. As the magnetic field changes over time, an induced electric field may be generated, and electrons accelerated by the induced electric field may collide with molecules or atoms of the etching gas, thereby generating plasma.

Then, an etching process may be performed by supplying ions of the plasma to the substrate W. As the substrate W is adsorbed and fixed by the electrostatic chuck 320, the etching process can be stably performed on the first surface S1 of the substrate W. Also, as the DLC film 140 is deposited on the second surface S2 of the substrate W, the substrate W can be stably fixed on the electrostatic chuck 320 without causing scratches or defects on the second surface S2 of the substrate W.

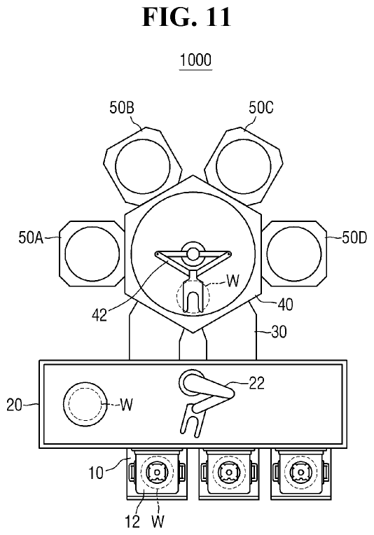

FIG. 11 is a schematic view of a semiconductor manufacturing system according to some embodiments of the present disclosure.

Referring to FIG. 11, a semiconductor manufacturing system 1000 may be a cluster system capable of processing multiple substrates W. The cluster system may refer to a multi-chamber-type substrate processing system including a transfer robot and a plurality of substrate processing modules, which are arranged around the transfer robot. The semiconductor manufacturing system 1000 may include load ports 10, an equipment front-end module (EFEM, 20), load lock chambers 30, a transfer chamber 40, and first, second, third, and fourth process chambers 50A, 50B, 50C, and 50D.

The load ports 10 may accommodate carriers 12 or front opening unified pods (FOUPs). The carriers 12 may load substrates W thereon. A transfer device (e.g., a hoist device) may load the carriers 12 on the load ports 10. When the manufacture of the substrates W is complete, the transfer device may transfer the carriers 12 to another location. The EFEM 20 may be provided between the load ports 10 and the load lock chambers 30. The EFEM 20 may have a first transfer arm 22. The first transfer arm 22 may unload the substrates W from the carriers 12 and may provide the substrates W to the load lock chambers 30. The first transfer arm 22 may provide the carriers 12 from the load lock chambers 30 to the carriers 12. The first transfer arm 22 may temporarily store the substrates W in the EFEM 20.

The load lock chambers 30 may be provided between the EFEM 20 and the transfer chamber 40. The load lock chambers 30 may change the external pressure applied to the substrates W. The load lock chambers 30 may provide atmospheric pressure and vacuum pressure to the substrates W. When the substrates W are provided from the EFEM 20 to the load lock chambers 30, the load lock chambers 30 may be pumped with vacuum pressure. When the substrates W are provided from the transfer chamber 40 to the load lock chambers 30, the load lock chambers 30 may be purged by a purge gas (e.g., N₂) and may thus have atmospheric pressure.

The transfer chamber 40 may be provided between the load lock chambers 30 and the first, second, third, and fourth process chambers 50A, 50B, 50C, and 50D. The transfer chamber 40 and the first, second, third, and fourth process chambers 50A, 50B, 50C, and 50D may have vacuum pressure. The transfer chamber 40 may include a second transfer arm 42. The second transfer arm 42 may be provided in the middle of the transfer chamber 40. The second transfer arm 42 may be provided to be moveable into the load lock chambers 30 and the first, second, third, and fourth process chambers 50A, 50B, 50C, and 50D. The second transfer arm 42 may retrieve the substrates W from the load lock chambers 30 and the first, second, third, and fourth process chambers 50A, 50B, 50C, and 50D.

The first, second, third, and fourth process chambers 50A, 50B, 50C, and 50D and the load lock chambers 30 may be connected along the transfer chamber 40 as a cluster. FIG. 11 illustrates that four process chambers are connected along the transfer chamber 40, but the invention is not limited thereto. Alternatively, the number of process chambers connected to the transfer chamber 40 may be less than or greater than 4.

The first, second, third, and fourth process chambers 50A, 50B, 50C, and 50D may perform unit processes for the substrates W. In some embodiments, the first, second, third, and fourth process chambers 50A, 50B, 50C, and 50D may perform different unit processes for the substrates W. For example, the first process chamber 50A may correspond to the DLC film deposition modules 100, 100A, and 100B of FIGS. 1, 2, and 3, the second and third process chambers 50B and 50C may correspond to the substrate processing module 300 of FIG. 9 and may perform different unit processes (e.g., etching and thin-film deposition processes), and the fourth process chamber 50D may correspond to the removal module 200A and 200B of FIGS. 7 and 8.

For example, a DLC film 140 may be deposited on a second surface S2 of a substrate in the first process chamber 50A, the substrate W may be transferred to the second process chamber 50B, and a first surface S1 of the substrate W may be etched in the second process chamber 50B. Thereafter, the substrate W may be transferred to the third process chamber 50C, and a thin film may be deposited on the first surface S1 of the substrate W, in the third process chamber 50C. Thereafter, the substrate W may be transferred to the fourth process chamber 50D, and the DLC film 140 on the second surface S2 of the substrate W may be removed in the fourth process chamber 50D.

A semiconductor device may be fabricated by processing each substrate W with DLC film deposition modules, substrate processing modules, and removal modules, which form the first, second, third, and fourth process chambers 50A, 50B, 50C, and 50D in the semiconductor manufacturing system 1000 that forms a cluster system.

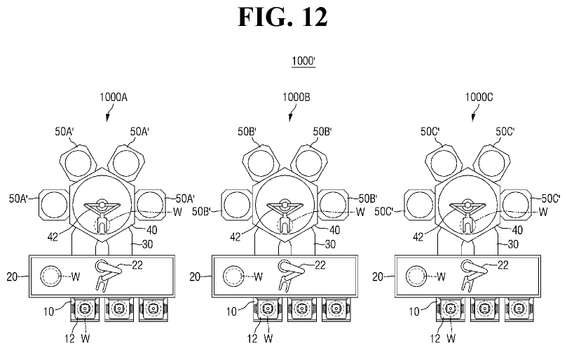

FIG. 12 is a schematic view of a semiconductor manufacturing system according to some embodiments of the present disclosure. The embodiment of FIG. 12 will hereinafter be described, focusing mainly on the differences with the embodiment of FIG. 11.

Referring to FIG. 12, a semiconductor manufacturing system 1000′ may be implemented as a single integral system including first, second, and third semiconductor manufacturing systems 1000A, 1000B, and 1000C. First process chambers 50A′ of the first semiconductor manufacturing system 1000A may all perform the same unit process on substrates W. Similarly, second process chambers 50B′ of the second semiconductor manufacturing system 1000B may all perform the same unit process on substrates W. Similarly, third process chambers 50C′ of the third semiconductor manufacturing system 1000C may all perform the same unit process on substrates W. For example, the unit process performed by the first process chambers 50A′ may be different from the unit process performed by the second process chamber 50B′ and different from the unit process performed by the third process chamber 50C′, and the unit process performed by the second process chambers 50B′ may be different from the unit process performed by the third process chamber 50C′.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

For example, the first process chambers 50A′ may correspond to one of the DLC film deposition modules 100, 100A, and 100B of FIGS. 1, 2, and 3. Accordingly, the first process chambers 50A′ of the first semiconductor manufacturing system 1000A may perform a DLC film deposition process on second surfaces S2 of a plurality of substrates W. The substrates W with DLC films 140 deposited thereon by the first semiconductor manufacturing system 1000A may be provided to the second semiconductor manufacturing system 1000B.

The second process chambers 50B′ of the second semiconductor manufacturing system 1000B may correspond to the substrate processing module 300 of FIG. 9. That is, the second process chambers 50B′ of the second semiconductor manufacturing system 1000B may all perform one of photolithography, etching, and deposition processes. Alternatively, the second process chambers 50B′ of the second semiconductor manufacturing system 1000B may perform photolithography, etching, and deposition processes, respectively. The substrates W processed by the second process chambers 50B′ may be provided to the third semiconductor manufacturing system 1000C. The third process chambers 50C′ of the third semiconductor manufacturing system 1000C may correspond to the removal module 200 or 200A of FIG. 7 or 8. Accordingly, the third process chambers 50C′ of the third semiconductor manufacturing system 1000C may remove the DLC films 140 deposited on the second surfaces S2 of the substrates W.

The first process chambers 50A′, the second process chambers 50B′, and the third process chambers 50C′, which form the first, second, and third semiconductor manufacturing systems 1000A, 1000B, and 1000C, respectively, that form a single cluster system together, perform the same respective processes, thereby improving the efficiency of the processing of the substrates W.

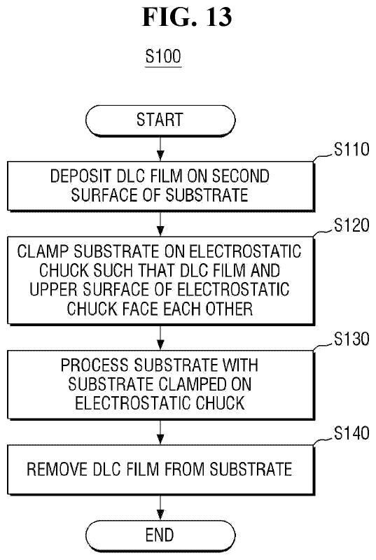

FIG. 13 is a flowchart illustrating method of manufacturing a semiconductor device according to some embodiments of the present disclosure.

In FIGS. 1 through 13, like reference numerals indicate like elements, and thus, detailed descriptions thereof will be omitted. FIG. 13 illustrates how to fabricate a semiconductor device using a semiconductor manufacturing system 1000′ including a DLC film deposition module 100, a removal module 200, and a substrate processing module 300, but alternatively, a semiconductor manufacturing system 1000′ including a DLC film deposition module 100A or 100B and/or a removal module 200A may be used.

As used herein, a semiconductor device may refer, for example, to a device such as a semiconductor chip (e.g., memory chip and/or logic chip formed on a die), a stack of semiconductor chips, a semiconductor package including one or more semiconductor chips stacked on a package substrate or wafer, or a package-on-package device including a plurality of packages. These devices may be formed using ball grid arrays, wire bonding, through substrate vias, or other electrical connection elements, and may include memory devices such as volatile or non-volatile memory devices. Semiconductor packages may include a package substrate, one or more semiconductor chips, and an encapsulant formed on the package substrate and covering the semiconductor chips.

Referring to FIG. 13, a DLC film 140 is deposited on a second surface S2 of a substrate W by the DLC film deposition module 100 (S110). The substrate W may have a first surface S1, which is disposed to face the top of a chamber 110, and the second surface S2, which is disposed to face the bottom of the chamber 110. The first surface S1 of the substrate W may correspond to the front side of the substrate W, and the second surface S2 of the substrate W may correspond to the back side of the substrate W. Referring again to FIG. 12, the first process chambers 50A′ of the first semiconductor manufacturing system 1000A may deposit DLC films 140 on second surfaces S2 of a plurality of substrates W at the same time, and the substrates W with the DLC films 140 deposited thereon may be transferred to the second semiconductor manufacturing system 1000B.

Thereafter, the substrate W is clamped on an electrostatic chuck 320 in a chamber 310 of the substrate processing module 300 (S120) such that the DLC film 140 and an upper surface 320A of the electrostatic chuck 320 face each other. Thereafter, the first surface S1 of the substrate W is processed by the substrate processing module 300 (S130). During the processing of the first surface S1 of the substrate W, the substrate W may be maintained to be clamped by the electrostatic chuck 320, in the chamber 310. Referring again to FIG. 12, the second process chambers 50B′ of the second semiconductor manufacturing system 1000B may process first surfaces S1 of a plurality of substrates W at the same time, and then, the substrates W may be transferred to the third semiconductor manufacturing system 1000C.

After the processing of the substrate W by the substrate processing module 300, the DLC film 140 is removed from the substrate W by the removal module 200 (S140). The processing of the substrate W by the substrate processing module 300 may require the clamping of the substrate W with the electrostatic chuck 320. That is, S140 may be a step where the substrate W is no longer in need of being clamped by the electrostatic chuck 320. Referring again to FIG. 12, the third process chambers 50C′ of the third semiconductor manufacturing system 1000C may remove DLC films 140 from second surfaces S2 of a plurality of substrates W at the same time.

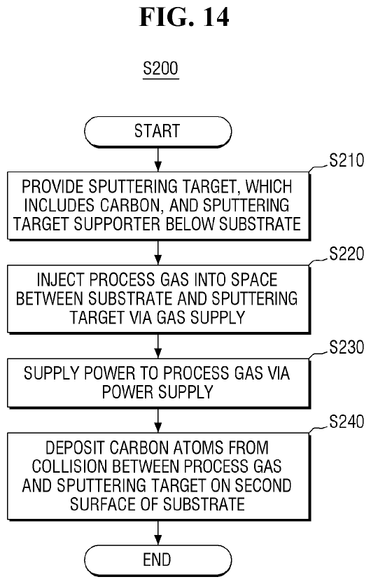

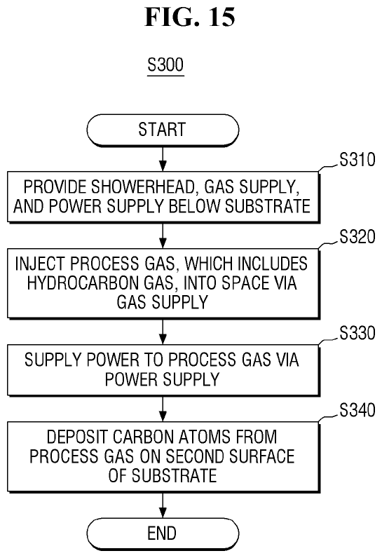

FIGS. 14 and 15 are flowcharts illustrating how to deposit a DLC film, as performed in the semiconductor device manufacturing method of FIG. 13.

FIG. 14 illustrates an operating method of the DLC film deposition module 100 of FIG. 1, and FIG. 15 illustrates an operating method of the DLC film deposition module 100A of FIG. 2. In FIGS. 1 and 14, like reference numerals indicate like elements, and thus, detailed descriptions thereof will be omitted. In FIGS. 2 and 15, like reference numerals indicate like elements, and thus, detailed descriptions thereof will be omitted.

Referring to FIG. 14, S200 may be performed using a DLC film deposition module 100 including a sputtering target 131, a sputtering target supporter 132, a gas supply 133, and a power supply 134. First, the sputtering target 131, which includes C, and the sputtering target supporter 132, which supports the sputtering target 131, are provided below a substrate W (S210). Thereafter, a process gas 136 is injected into the space between the substrate W and the sputtering target 131, in a chamber 110, by the gas supply 133 (S220). Thereafter, power is supplied to the process gas 136 between the substrate W and the sputtering target 131 by the power supply 134 (S230). Specifically, an electric field may be applied to the space between the substrate W and the sputtering target 131, thereby turning the process gas 136 into plasma. Thereafter, positive ions of the process gas 136 accelerated by the supplied power are made to collide with the sputtering target 131, and C atoms popped out of the sputtering target 131 due to the collision between the positive ions of the process gas 136 and the sputtering target 131 are deposited on a second surface S2 of the substrate W (S240).

Referring to FIG. 15, S300 may be performed by a DLC film deposition module 100A including a showerhead 150, a gas supply 133A, and a power supply 134A. First, the showerhead 150, the gas supply 133A, and the power supply 134A are provided below a substrate W (S310). The gas supply 133A may inject a process gas 136A including a hydrocarbon gas into a first space SP1 between a substrate W and the showerhead 150 via the showerhead 150 (S320). The power supply 134A may supply power to the process gas 136A to turn the process gas 136A into plasma (S330). Accordingly, the process gas 136A including the hydrocarbon gas may be turned into plasma containing C atoms. Then, the C atoms from the process gas 136A are deposited on a second surface S2 of the substrate W (S340).

In some embodiments, referring to FIG. 3, the semiconductor device manufacturing method of FIG. 13 may further include providing a showerhead 150B above the substrate W, providing a gas supply 133B, which injects a process gas 136B into a second space SP2 between the substrate W and a showerhead 150B, via the showerhead 150B, and injecting the process gas 136B into the second space SP2 via the gas supply 133B.

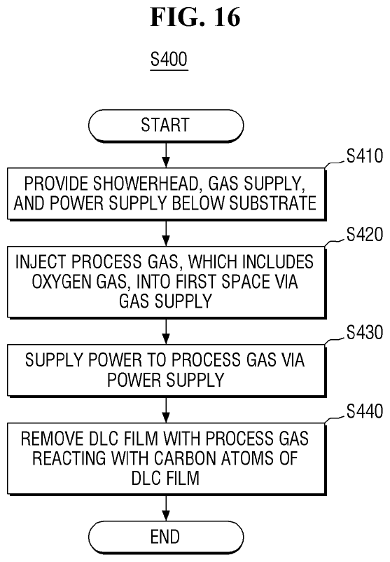

FIG. 16 is a flowchart illustrating how to remove a DLC film, as performed in the semiconductor device manufacturing method of FIG. 13.

In FIGS. 7 and 16, like reference numerals indicate like elements, and thus, detailed descriptions thereof will be omitted. In the embodiment of FIG. 16, the removal module 200 of FIG. 7 may be used to remove a DLC film 140, but alternatively, the removal module 200A of FIG. 8 may be used.

Referring to FIG. 16, S400 may be performed by a removal module 200 including a showerhead 250, a gas supply 233, and a power supply 234. First, the showerhead 250, the gas supply 233, and the power supply 234 are provided below a substrate W (S410). The gas supply 233 may inject a process gas 236 including O₂ gas into a first space SP1′ between the substrate W and the showerhead 250 via the showerhead 250 (S420). The power supply 234 may supply power to the process gas 236 via the showerhead 250 to turn the process gas 236 into plasma (S430). Accordingly, the process gas 236 containing the O₂ gas may be turned into plasma containing oxygen radicals. The oxygen radicals react with C atoms from a DLC film 140 deposited on a second surface S2 of the substrate W, and as a result, the DLC film 140 is removed from the substrate W (S440). That is, as a result of the reaction between the oxygen radicals, which are highly reactive, and the C atoms from the DLC film 140, CO or CO₂ may be generated and may be released to the outside of a chamber 210 through an outlet 213.

In some embodiments, referring to FIG. 8, the semiconductor device manufacturing method of FIG. 13 may further include providing a showerhead 250A above the substrate W, providing a gas supply 233A, which injects a process gas 236A into a second space SP2′ between the substrate W and a showerhead 250A, via the showerhead 250A, and injecting the process gas 236A into the second space SP2′ via the gas supply 233A.

Although the embodiments of the present disclosure have been described with reference to the accompanying drawings, the invention is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

1. A diamond-like carbon (DLC) film deposition apparatus comprising:
a chamber;
a holder in the chamber, the holder configured to support a mounted substrate while being in contact with part of a second surface of the mounted substrate, wherein the mounted substrate is a substrate placed on the holder and having a first surface facing the top of the chamber and the second surface opposite to the first surface; and
a DLC film generator below the holder, in the chamber, the DLC film generator configured to deposit a DLC film on the second surface of the mounted substrate.

2. The DLC film deposition apparatus of claim 1, wherein the DLC film generator includes:
a sputtering target facing the second surface of the mounted substrate,
a sputtering target supporter having an upper surface where the sputtering target is loaded,
a gas supply configured to inject a process gas into a space between the mounted substrate and the sputtering target, and
a power supply configured to supply power to the process gas to generate plasma in the space between the mounted substrate and the sputtering target.

3. The DLC film deposition apparatus of claim 2, wherein the sputtering target includes carbon (C).

4. The DLC film deposition apparatus of claim 1, wherein the DLC film generator includes:
a first showerhead facing the second surface of the mounted substrate,
a first gas supply configured to inject a first process gas into a first space between the mounted substrate and the first showerhead via the first showerhead, and
a power supply configured to supply power to the first process gas to generate plasma in the first space.

5. The DLC film deposition apparatus of claim 4, wherein the first process gas includes a hydrocarbon gas.

6. The DLC film deposition apparatus of claim 4, further comprising:
a second showerhead above the substrate facing the first surface of the mounted substrate; and
a second gas supply configured to inject a second process gas into a second space between the mounted substrate and the second showerhead via the second showerhead.

7. The DLC film deposition apparatus of claim 6, wherein the second process gas includes at least one of nitrogen (N₂) and argon (Ar).

8. The DLC film deposition apparatus of claim 1, wherein a silicon film is formed between the second surface of the substrate and the DLC film.

9. The DLC film deposition apparatus of claim 8, wherein the silicon film includes SiO₂ or SiN.

10. The DLC film deposition apparatus of claim 1, wherein the DLC film generator is configured to deposit the DLC film having a hardness of 10 GPa to 50 GPa.

11. The DLC film deposition apparatus of claim 1, wherein the DLC film generator is configured to deposit the DLC film having a thickness of 10 nm to 500 nm.

12. A semiconductor manufacturing system comprising:
a first chamber;
a diamond-like carbon (DLC) film deposition module configured to deposit a DLC film on a second surface of a substrate, the substrate, when disposed in the first chamber, having a first surface facing the top of the first chamber and the second surface opposite to the first surface; and
a substrate processing module including a second chamber different from the first chamber and an electrostatic chuck, the electrostatic chuck configured to support the second surface of the substrate, the substrate processing module configured to process the first surface of the substrate with the DLC film deposited on the second surface; and
a holder in the chamber and configured to support part of the second surface of the substrate while the DLC film deposition module is depositing the DLC film on the second surface of the substrate, wherein:
while the DLC film deposition module is depositing the DLC film on the second surface of the substrate, a part of the second surface of the substrate is supported by the holder in the first chamber, and
the electrostatic chuck is configured to fix the substrate such that the DLC film and an upper surface of the electrostatic chuck face each other while the substrate processing module is processing the first surface of the substrate.

13. The semiconductor manufacturing system of claim 12, further comprising:
a removal module configured to remove the DLC film from the substrate after the processing of the first surface of the substrate by the substrate processing module.

14. A method of manufacturing a semiconductor device, the method comprising:
depositing a diamond-like carbon (DLC) film on a second surface of a substrate, the substrate having a first surface facing the top of a first chamber, and the second surface opposite to the first surface;
in a second chamber different from the first chamber, fixing the substrate on an electrostatic chuck such that the DLC film and an upper surface of the electrostatic chuck face each other; and
processing the first surface of the substrate with the substrate clamped on the electrostatic chuck, in the second chamber.

15. The method of claim 14,
wherein the depositing the DLC film on the second surface of the substrate comprises:
providing a sputtering target, which includes carbon (C), and a sputtering target supporter, which is configured to support the sputtering target, below the substrate,
injecting a process gas into a space between the substrate and the sputtering target via a gas supply,
supplying power to the process gas in the space between the substrate and the sputtering target via a power supply, and
depositing C atoms, which are obtained from a collision of the process gas supplied with the power and the sputtering target, on the second surface of the substrate.

16. The method of claim 14, wherein the depositing the DLC film on the second surface of the substrate comprises:
providing a first showerhead, a first gas supply configured to inject a first process gas into a first space between the substrate and the first showerhead via the first showerhead, and a power supply configured to supply power to the first process gas, below the substrate,
injecting the first process gas, which includes a hydrocarbon gas, into the first space via the first gas supply,
supplying power to the first process gas in the first space via the power supply, and
depositing C atoms, which are obtained from the supplying power to the first process gas, on the second surface of the substrate.

17. The method of claim 16, wherein the depositing the DLC film on the second surface of the substrate, further comprises:
providing, above the substrate, a second showerhead and a second gas supply configured to inject a second process gas into a second space between the substrate and the second showerhead via the second showerhead; and
injecting the second process gas into the second space via the second gas supply.

18. The method of claim 17, wherein the second process gas includes at least one of nitrogen (N₂) and argon (Ar).

19. The method of claim 14, further comprising:
removing the DLC film from the substrate after the processing the first surface of the substrate,
wherein the removing the DLC film from the substrate comprises:
providing, below the substrate, a first showerhead, a first gas supply configured to inject a first process gas into a first space between the substrate and the first showerhead via the first showerhead, and a power supply configured to supply power to the first process gas,
injecting the first process gas, which includes an oxygen (O₂) gas, into the first space via the first gas supply,
supplying power to the first process gas in the first space via the power supply, and
removing the DLC film from the substrate by causing the first process gas supplied with power to react with C atoms of the DLC film.

20. The method of claim 14, wherein the processing the first surface of the substrate comprises performing at least one of etching, photolithography, and deposition processes on the first surface of the substrate.

21-32. (canceled)
